(19) United States
(12) Patent Application Publication
(10) Pub. No.: US 2015/0069441 A1
(43) Pub. Date: Mar. 12, 2015

(54) LIGHT EMITTING DIODE PACKAGE

(71) Applicant: ADVANCED OPTOELECTRONIC TECHNOLOGY, INC., Hsinchu Hsien 303 (TW)

(72) Inventors: HOU-TE LIN, Hukou (TW); FU-HSIANG YEH, Hukou (TW); CHAO-HSIUNG CHANG, Hukou (TW); PIN-CHUAN CHEN, Hukou (TW); LUNG-HSIN CHEN, Hukou (TW)

(21) Appl. No.: 14/476,147

(22) Filed: Sep. 3, 2014

(30) Foreign Application Priority Data
Sep. 9, 2013 (CN) 201310405001X

(51) Int. Cl. H01L 33/38; H01L 33/54; H01L 33/62; H01L 33/60

(52) U.S. Cl. CPC H01L 33/38; H01L 33/60; H01L 33/54; H01L 33/62
USPC 257/98

(57) ABSTRACT

A light emitting diode (LED) package includes a substrate, a first electrode and a second electrode mounted on opposite sides of the substrate, an LED chip mounted on a top surface of one of the electrodes and electrically connecting the first electrode and the second electrode by wire bonding, and a reflecting cup enclosing an outer periphery of the first electrode and the second electrode to expose top surfaces of the first electrode and the second electrode and bottom surfaces of the first electrode and the second electrode.

### FIELD

The present disclosure generally relates to solid state light emitting sources and, more particularly, to a light emitting diode (LED) package.

### BACKGROUND

LEDs have many advantages, such as high luminosity, low operational voltage, low power consumption, compatibility with integrated circuits, easy driving, long term reliability, and environmental friendliness which have promoted the wide use of LEDs as a light source.

A typical LED package includes two electrodes, an LED chip mounted on one of the electrodes and electrically connecting the electrodes by wire bonding, and a reflecting surface enclosing the LED chip and mounted on top surfaces of the electrodes. Generally, the reflecting cup occupies most of the top surfaces of the electrodes.

### BRIEF DESCRIPTION OF THE DRAWINGS

Implementations of the present technology will now be described, by way of example only, with reference to the attached figures.

FIG. 1 is a bottom plan view of an LED package according to a first embodiment of the present disclosure.

FIG. 2 is a cross-sectional view of the LED package of FIG. 1, taken along II-II line thereof

FIG. 3 is a cross-sectional view of an LED package according to a second embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The term “comprising,” when utilized, means “including, but not necessarily limited to”; it specifically indicates open-ended inclusion or membership in the so-described combination, group, series and the like.

Embodiments of an LED package in accordance with the present disclosure will now be described in detail below and with reference to the drawings.

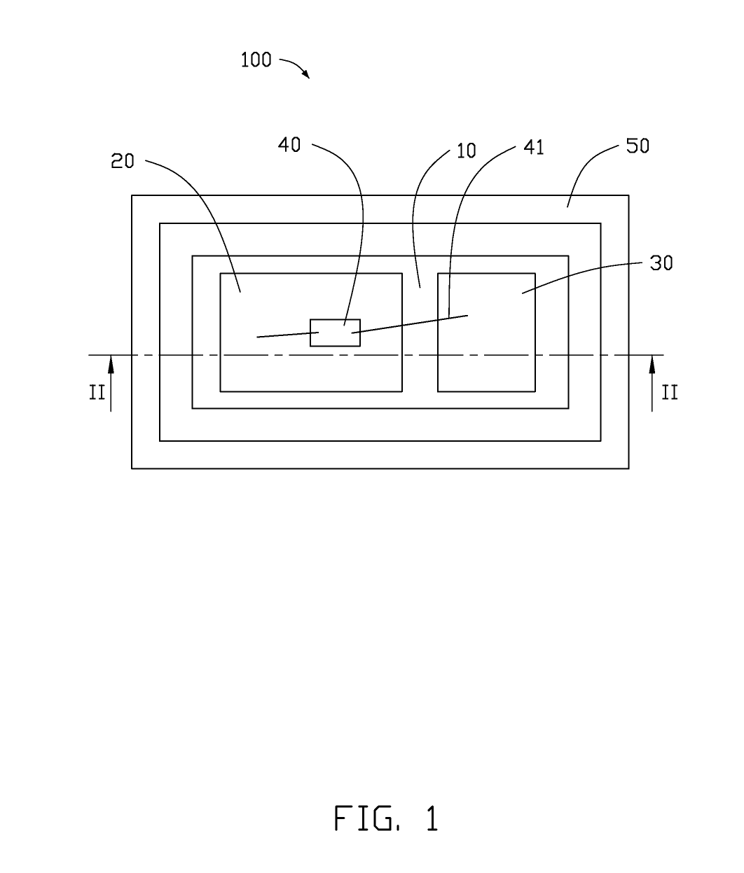

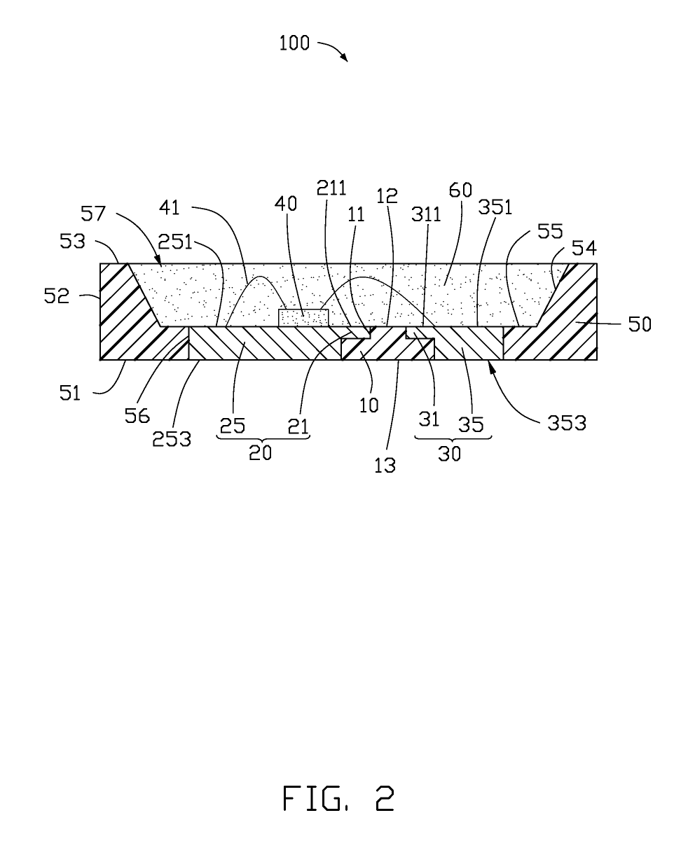

Referring to FIGS. 1-2, an LED package 100 in accordance with a first embodiment of the disclosure includes a substrate 10, a first electrode 20, and a second electrode 30 mounted on opposite sides of the substrate 10, an LED chip 40 mounted on the first electrode 20, a reflecting cup 50 enclosing the first electrode 20 and the second electrode 30, and a package layer 60 filled in the reflecting cup 50.

The substrate 10 is an electrically insulating layer to electrically insulate the first electrode 20 and the second electrode 30. The substrate has a T-shaped configuration. Two L-shaped recesses 11 are defined in opposite sides of the substrate 10. The substrate 10 includes a top surface 12 and a bottom surface 13 parallel to the top surface 12.

The first electrode 20 includes a main body 25 and a first arm 21 extending from a top end of a right side of the main body 25. A top surface 251 of the main body 25 and a top surface 211 of the first arm 21 are coplanar and cooperatively form a top surface of the first electrode 20. A bottom surface 253 of the main body 25 is a bottom surface of the first electrode 20.

The second electrode 30 includes a main body 35 and a second arm 31 extending from a top end of a left side of the main body 35. A top surface 351 of the main body 35 and a top surface 311 of the first arm 31 are coplanar and cooperatively form a top surface of the second electrode 30. A bottom surface 353 of the main body 35 is a bottom surface of the second electrode 30.

The first arm 21 and the second arm 31 match the recesses 11 of the substrate 10 and are embedded in the recesses 11, respectively. In this state, the first electrode 20 and the second electrode 30 are firmly mounted on the substrate 10. The top surfaces of the first electrode 20 and the second electrode 30 are coplanar with the top surface 12 of the substrate 10; the bottom surfaces of the first electrode 20 and the second electrode 30 are coplanar with the bottom surface 13 of the substrate 10. The LED chip 40 is mounted on a central portion of the top surface of the first electrode 20. Wires 41 of the LED chip 40 electrically connect the first electrode 20 and the second electrode 30.

The reflecting cup 50 encloses an outer periphery of the first electrode 20 and the second electrode 30. The bottom surfaces of the first electrode 20 and the second electrode 30 are exposed from the reflecting cup 50.

The reflecting cup 50 includes a bottom surface 51, a side surface 52 and a contacting surface 56 extending upward from opposite sides of the bottom surface 51, a top surface 53 bent from a top end of the side surface 52, a reflecting surface 54 extending slantingly downward and from a free end of the top surface 53, and a transition surface 55 extending from a free end of the reflecting surface 54 and connecting the second surface 56. The bottom surface 51 is a flat surface and coplanar with the bottom surface of the first electrode 20. The side surface 52 and the contacting surface 56 are parallel and perpendicular to the bottom surface 50. A height of the side surface 52 is larger than that of the second side surface 53. The top surface 53 is parallel to the bottom surface 51 and located at a top of the second side surface 52. A width of the top surface 53 is less than that of the bottom surface 51. The transition surface 55 is coplanar with the top surface of the first electrode 20 and located at an outer side of the first electrode 20 and the second electrode 30. The contacting surface 56 firmly contacts the outer periphery of the first electrode 20 and the second electrode 30. The reflecting surface 54, the transition surface 55, and the top surfaces of the first electrode 20, the second electrode 30 and the substrate 10 cooperatively define a receiving space 57 therebetween to receive the packaging layer 60 therein. A depth of the receiving space 57 is larger than a height of the LED chip 40. A bore diameter of the receiving space 57 decreases from top to bottom.

The packaging layer 60 is transparent and made of a silicon or epoxy resin. A plurality of phosphorus powder can be doped in the packaging layer 60. The packaging layer 60 fills in the receiving space 57 to envelope the LED chip 40 therein.

In this embodiment, the reflecting cup 50 is mounted on the outer periphery of the first electrode 20 and the second electrode 30, thus the entirety of the top surfaces of the first electrode 20 and the second electrode 30 are exposed from the reflecting cup 50 to engage the LED chip 40 and the wires 41. The transition surface 54 located at an outer side of the LED chip 40 can reflect light emitted from the LED chip 40 out to enhance the light extraction efficiency of the LED package 100.

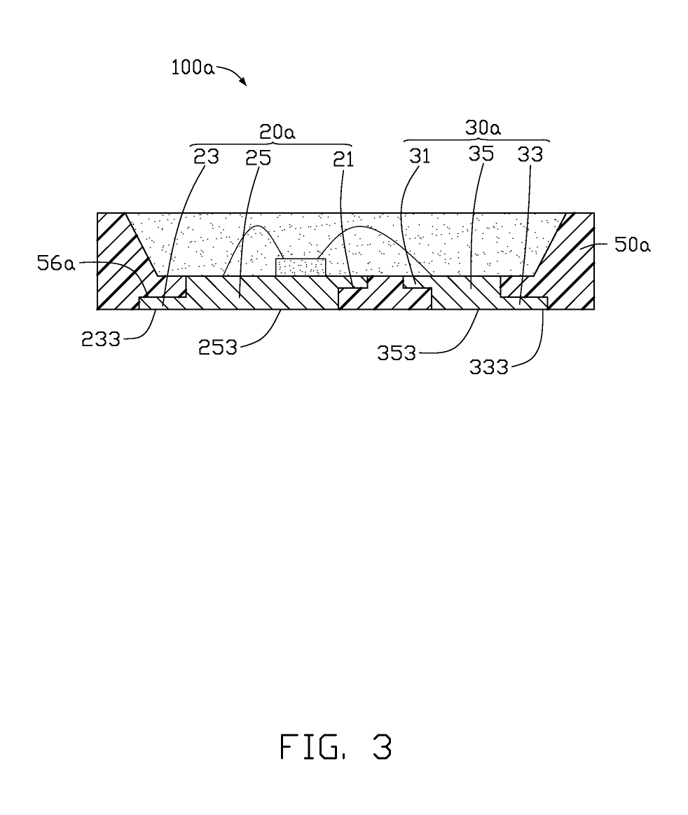

Referring to FIG. 3, an LED package 100a of a second embodiment is shown. The LED package 100a is similar to the LED package 100 of the first embodiment, and differences therebetween are that a first electrode 20a further includes a third arm 23 extending from a bottom end of a left side of a main body 25, and a second electrode 30a further includes a fourth arm 33 extending from a bottom end of a right side of a main body 35. The third arm 23 and the fourth arm 33 are embedded in a bottom end of the reflecting cup 50a. A bottom surface 233 of the third arm 23 is coplanar with a bottom surface 253 of the main body 25. The bottom surfaces 233, 253 of the third arm 23 and the main body 25 are cooperatively form a bottom surface of the first electrode 20a. A bottom surface 333 of the fourth arm 33 is coplanar with the bottom surface 353 of the main body 35. The bottom surfaces 333, 353 of the fourth are 33 and the main body 35 are cooperatively form a bottom surface of the second electrode 30a. The bottom surfaces of the first electrode 20a and the second electrode 30a are exposed from the reflecting cup 50a, and are coplanar.

The embodiments shown and described above are only examples. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A light emitting diode (LED) package comprising:
a substrate;
a first electrode and a second electrode mounted on opposite sides of the substrate;
an LED chip mounted on a top surface of one of the electrodes and electrically connecting the first electrode and the second electrode by wire bonding; and
a reflecting cup enclosing an outer periphery of the first electrode and the second electrode to expose top surfaces of the first electrode and the second electrode and bottom surfaces of the first electrode and the second electrode.

2. The LED package of claim 1, wherein the reflecting cup comprises a contacting surface which firmly contacts the outer periphery of the first electrode and the outer periphery of the second electrode, a transition surface extending outwardly from a top end of the contacting surface, and a reflecting surface extending upwardly and slantwise from the transition surface, wherein the transition surface and the reflecting surface cooperatively define a receiving space therebetween.

3. The LED package of claim 2, wherein a bore diameter of the receiving space decreases from top to bottom.

4. The LED package of claim 2, wherein a package layer is filled in the receiving space to envelope the LED chip therein.

5. The LED package of claim 2, wherein the top surfaces of the first electrode and the second electrode are coplanar with the transition surface.

6. The LED package of claim 5, wherein the reflecting cup comprises a bottom surface, the contacting surface extends upwardly from a side of the bottom surface, and the bottom surface of the reflecting cup is coplanar with the bottom surfaces of the first electrode and the second electrode.

7. The LED package of claim 6, wherein the first electrode comprises a main body and a first arm extending from the main body, the second electrode comprises a main body and a second arm extending from the maim body, and the first arm and the second arm are embedded in opposite sides of a top end of the substrate.

8. The LED package of claim 7, wherein a top surface of the main body of the first electrode is coplanar with a top surface of the first arm and cooperates with the top surface of the first arm to form the top surface of the first electrode.

9. The LED package of claim 7, wherein a top surface of the main body of the second electrode is coplanar with a top surface of the second arm and cooperates with the top surface of the second arm to form the top surface of the first electrode.

10. The LED package of claim 7, wherein the first electrode comprises a third arm extending from the main body, the second electrode comprises a fourth arm extending from the maim body, and the third arm and the fourth arm are embedded in a bottom end of the reflecting cup.

11. The LED package of claim 10, wherein a bottom surface of the main body of the first electrode is coplanar with a bottom surface of the third arm and cooperates with the bottom surface of the third arm to form the bottom surface of the first electrode.

12. The LED package of claim 10, wherein a bottom surface of the main body of the second electrode is coplanar with a bottom surface of the fourth arm and cooperates with the bottom surface of the fourth arm to form the bottom surface of the second electrode.
